(19) United States
(12) Patent Application Publication
(10) Pub. No.: US 2026/0005144 A1
(43) Pub. Date: Jan. 1, 2026

(54) DEVICE COMPRISING A METALLIC WIRE AND FABRICATION PROCESS OF THE DEVICE

(71) Applicant: STMicroelectronics International N.V., Geneva (CH)

(72) Inventors: Hugo NUEZ, Grenoble (FR); Frederic BATTEGAY, Crolles (FR); Pierre TISSIER, Grenoble (FR); Philippe BRUN, Grenoble (FR)

(73) Assignee: STMicroelectronics International N.V., Geneva (CH)

(21) Appl. No.: 19/248,238

(22) Filed: Jun. 24, 2025

(30) Foreign Application Priority Data
Jun. 27, 2024 (FR) FR2406910

(51) Int. Cl. H01L 23/532; H01L 21/768

(52) U.S. Cl. CPC H01L 23/53238; H01L 21/76841; H01L 23/53266

(57) ABSTRACT

A device comprising a first layer, a trench partially running through the first layer extending from a first side, and being filled with a conductive etch stop layer, a conductive barrier layer covering the conductive etch stop layer, and a track of a first metallic material in contact with the barrier layer, in the trench, an opening in the first layer extending from a second side, opposite to the first side, of the dielectric or semiconductor layer, the opening running through the first layer all the way to the etch stop layer, and a first layer of a second metallic material covering the walls of the opening.

### CROSS-REFERENCE TO RELATED APPLICATION(S)

This application claims the priority benefit of French patent application number FR2406910, filed on Jun. 27, 2024, entitled “Dispositif comprenant une piste métallique et procédé de fabrication du dispositif,” which is hereby incorporated by reference to the maximum extent allowable by law.

### BACKGROUND

### Technical Field

The present disclosure generally concerns electronic devices and their manufacturing processes.

### Description of the Related Art

In microelectronics, a device may comprise conductive tracks connected to connection pads. Certain metallic materials, for example copper, present a risk of electromigration when they are crossed by a significant electric current, and present a risk of corrosion when they are in contact with a humid environment. To mitigate these risks, it is known to position a diffusion barrier layer in contact with these metallic materials to limit the electromigration phenomenon.

However, existing solutions for forming such devices present the risk for the connection pads not to be sufficiently protected against electromigration and corrosion.

There exists a need to improve devices comprising one or a plurality of metal tracks connected to connection pads and their manufacturing processes.

### BRIEF SUMMARY

An embodiment provides a device comprising, on a substrate, a dielectric or semiconductor layer, a trench in the dielectric or semiconductor layer extending from a first side of the dielectric or semiconductor layer, the trench partially running through the dielectric or semiconductor layer and being filled with a conductive etch stop layer covering the walls of the trench and in contact with the dielectric or semiconductor layer, a conductive barrier layer covering the conductive etch stop layer, and a track of a first metallic material in contact with the barrier layer, in the trench. The device includes an opening in the dielectric or semiconductor layer extending from a second side, opposite to the first side, of the dielectric or semiconductor layer, the opening running through the dielectric or semiconductor layer all the way to the etch stop layer, and a first layer of a second metallic material covering the walls of the opening.

According to an embodiment, the first layer of the second metallic material forms a connection pad.

According to an embodiment, the device comprises a second layer of a third metallic material covering the first layer, the third metallic material being, for example, gold, titanium, or titanium tungsten.

According to an embodiment, the track is a safety track configured to break in case of a tearing or of a breakage of the optical diffuser.

Another embodiment provides a manufacturing process comprising, on a substrate, an etching of a trench in a dielectric or semiconductor layer extending from a first side of the dielectric or semiconductor layer, the trench partially running through the dielectric or semiconductor layer, a deposition of a conductive etch stop layer covering the walls of the trench and in contact with the dielectric or semiconductor layer, a deposition of a conductive barrier layer covering the conductive etch stop layer, a deposition of a track of a first metallic material in contact with the barrier layer, into the trench, an etching of an opening in the dielectric or semiconductor layer extending from a second side, opposite to the first side, of the dielectric or semiconductor layer, the opening running through the dielectric or semiconductor layer until exposing a portion of the conductive etch stop layer, and, a deposition of a first layer of a second metallic material covering the walls of the opening.

According to an embodiment, the process further comprises, prior to the step of deposition of the track, a step of deposition of particles of the first metallic material on the surface of the barrier layer, the particles being used as seeds for the deposition of the track.

According to an embodiment, the deposition of the track is performed by electroplating.

According to an embodiment, the method further comprises, prior to the etching of the opening, a thinning step to expose the dielectric or semiconductor layer outside the trench.

According to an embodiment, the opening is formed by plasma etching.

According to an embodiment, the process further comprises, prior to the etching of the opening, the thinning of the substrate to expose the second side of the dielectric or semiconductor layer.

According to an embodiment, the conductive etch stop layer is made of titanium nitride and for example has a maximum thickness in the range from 30 nm to 100 nm.

According to an embodiment, the barrier layer is made of tantalum nitride or of tantalum.

According to an embodiment, the first metallic material is copper.

According to an embodiment, the second metallic material is gold, titanium, or tungsten titanium.

According to an embodiment, the use of the device described hereabove comprises the application of a current to the track and the detection of an open circuit preventing the conduction of this current.

### BRIEF DESCRIPTION OF THE SEVERAL VIEWS OF THE DRAWINGS

The foregoing features and advantages, as well as others, will be described in detail in the rest of the disclosure of specific embodiments given as an illustration and not limitation with reference to the accompanying drawings, in which:

FIG. 1A and FIG. 1B are cross-section views of a device comprising a metal track according to an embodiment of the present disclosure;

FIG. 2A, FIG. 2B, FIG. 2C, FIG. 2D, FIG. 2E, FIG. 2F, and FIG. 2G are perspective and cross-section views, and FIG. 2H, FIG. 2I, and FIG. 2J are cross-section views of successive steps of a process for manufacturing the device of FIGS. 1A and 1B according to an embodiment of the present disclosure;

FIG. 3 is a partial cross-section view of another device comprising a metal track according to an embodiment of the present disclosure, acquired by transmission electron microscopy and energy-dispersive X-ray spectroscopy;

FIG. 4A shows titanium atoms comprised in the device of FIG. 3; and

FIG. 4B shows tantalum atoms comprised in the device of FIG. 3.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the manufacturing processes involved in the manufacturing of an electronic device such as photolithography, the various types of etching and the deposition processes, are known to those skilled in the art.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front,” “back,” “top,” “bottom,” “left,” “right,” etc., or relative position qualifiers, such as “top,” “bottom,” “upper,” “lower,” etc., or orientation qualifiers, such as “horizontal,” “vertical,” etc., reference is made unless otherwise specified to the orientation of the drawings.

Unless specified otherwise, the expressions “about,” “approximately,” “substantially,” and “in the order of” signify plus or minus 10%, preferably of plus or minus 5%.

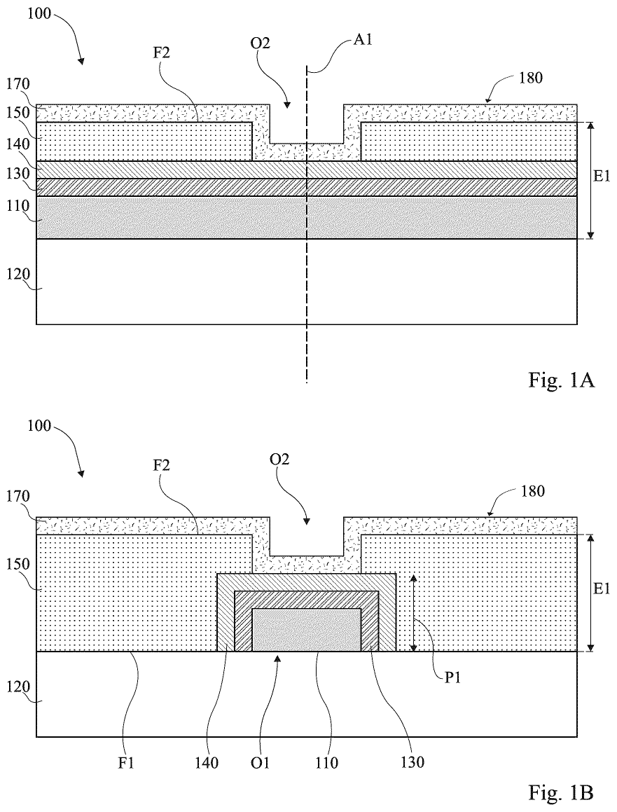

FIGS. 1A and 1B are cross-section views of a device 100 comprising a metal track 110 according to an embodiment of the present disclosure. FIG. 1B corresponds to a cross-section view of the device 100 of FIG. 1A along axis A1.

Device 100 for example comprises a substrate 120. Substrate 120 is, for example, a silicon or glass wafer.

Metal track 110 is formed on substrate 120, for example in direct contact with its surface. Metal track 110 is a conductive track configured to conduct an electric current. Metal track 110 is made of a first metallic material, for example copper, aluminum, etc. Metal track 110 for example has a thickness in the range from 100 nm to 250 nm, for example from 160 nm to 200 nm.

A diffusion barrier layer 130 covers metal track 110. Layer 130 covers, for example, the upper side and the flanks of metal track 110. Layer 130 is made of a first conductive material, for example tantalum nitride and/or tantalum, aluminum, etc. In other embodiments, layer 130 is made of another conductive material capable of forming a diffusion barrier layer. Layer 130 is configured, for example, to protect metal track 110. Layer 130 is configured, for example, to prevent or to decrease an electromigration of atoms from metal track 110 to surrounding layers. Layer 130 is conductive and electrically connected to metal track 110. Layer 130 for example has a thickness in the range from 5 nm to 25 nm, for example from 10 nm to 15 nm.

An etch stop layer 140 for example covers the upper side and the flanks of layer 130. Layer 140 is made of a second conductive material, for example titanium nitride, tantalum nitride, etc. Layer 140 is for example configured to protect layer 130. During an etch step configured to expose etch stop layer 140, layer 140 is for example configured so that layer 130 is not damaged by the etching. Layer 140 is for example at least partially sacrificed during the etch step and layer 130 for example remains intact. Layer 140 for example comprises portions which remain intact during the etch step and retain an initial thickness corresponding to the maximum thickness of layer 140 after the etch step. Layer 140 for example has a maximum thickness in the range from 30 nm to 100 nm, for example from 40 nm to 60 nm. According to an embodiment, layer 140 has for example a maximum thickness greater than 2% of the thickness of all the layers to be etched, and for example a maximum thickness in the range from 2% to 4% of the thickness of all the layers to be etched. Layer 140 is conductive and electrically connected to layer 130. Titanium nitride has a high resistivity and is not currently used to form an etch stop layer. However, it is a material resistant to an etching process, for example to a plasma etching process, and the selection of the thickness of layer 140 enables it to overcome the high resistivity.

In some embodiments, the layer 140 of the device 100, 100′, 300 is continuous. In other words, the layer 140 does not have openings or holes. The layer 140 is continuous between the barrier layer 130 and the layer 170 such that the barrier layer 130 is not in direct contact with layer 170. The layer 140 is a continuous layer over the barrier layer 130. The layer entirely or substantially entirely covers layer 130 inside the opening O2. Layer 140 has its initial thickness or is for example partially etched. Layer 140 has a minimum thickness greater than or equal to 20 nm in opening O2.

A dielectric, insulating, or semiconductor layer 150 is formed on substrate 120. Metal track 110 and layers 130 and 140 are for example in a trench or recess O1 of layer 150 so that layer 150 is in contact with layer 140. The thickness E1 of layer 150 is, for example, greater than the depth P1 of trench O1. Trench O1 extends from a first side F1 of layer 150, trench O1 partially crossing layer 150. Layer 150 comprises an opening O2 in layer 150 extending from a second side F2 of layer 150, side F2 being opposite to side F1. Opening O2 partially runs across the thickness of layer 150 and extends all the way to layer 140. Layer 150 is, for example, silicon, silicon oxide, tetraethyl orthosilicate, etc. According to an embodiment, layer 150 comprises an assembly of dielectric and/or semiconductor layers. Layer 150 for example has a thickness in the range from 1 μm to 2.5 μm, for example from 1.5 μm to 2 μm.

A first metallization or conductive layer 170, made of a second metallic material, is in contact with layer 150 and layer 140. Layer 170 is formed on the second side F2 of layer 150 and covers the flanks of layer 150 in opening O2. Layer 170 covers the portion of layer 140 exposed by opening O2. According to an embodiment, layer 140 is not continuous: it has, for example, been partially damaged during the creation of opening O2. Layer 170 is for example made of gold, of titanium, of titanium tungsten, of titanium nitride, etc. Layer 170 is electrically connected to layer 140, to layer 130, and to metal track 110. Layer 170 is for example at the surface of device 100 and in contact with the outer environment.

Layer 170 is, for example, a connection pad 180 of device 100, for example configured to connect device 100 to an external electronic circuit, not shown.

The presence of etch stop layer 140 in the stack comprising this layer 140 and diffusion barrier layer 130 has the advantage of protecting diffusion barrier layer 130 during an etching phase and of preventing an electromigration of the atoms of metal track 110 to the first metallization layer 170 and a corrosion of metal track 110.

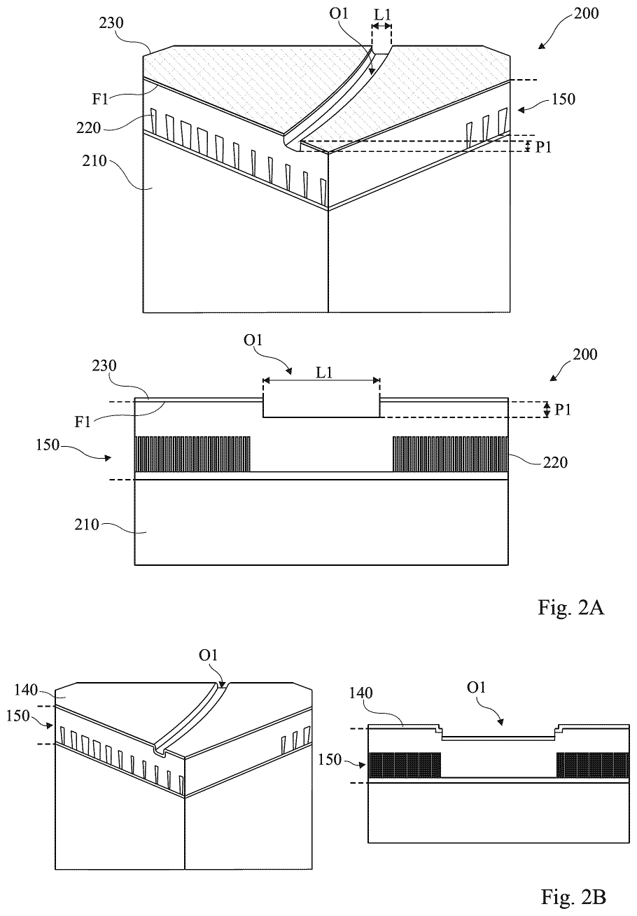

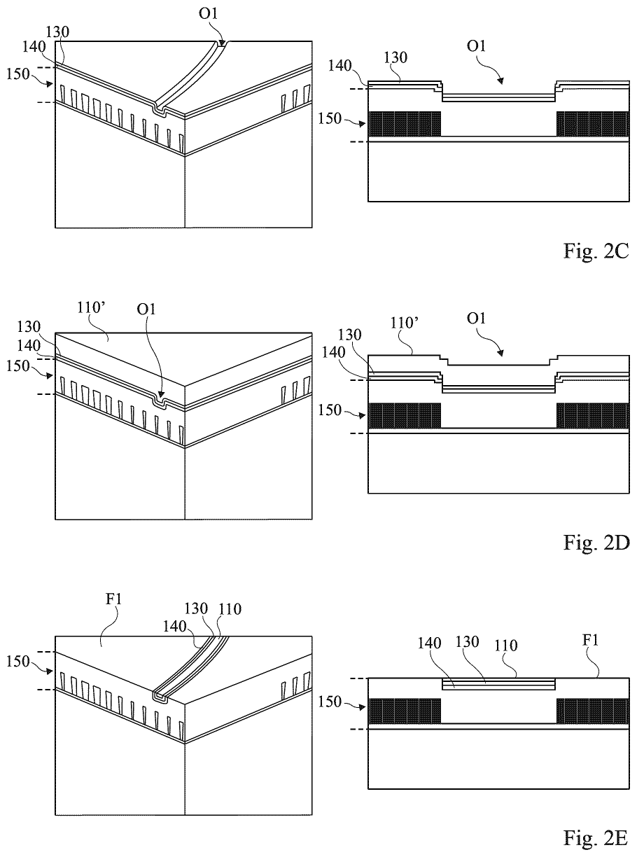

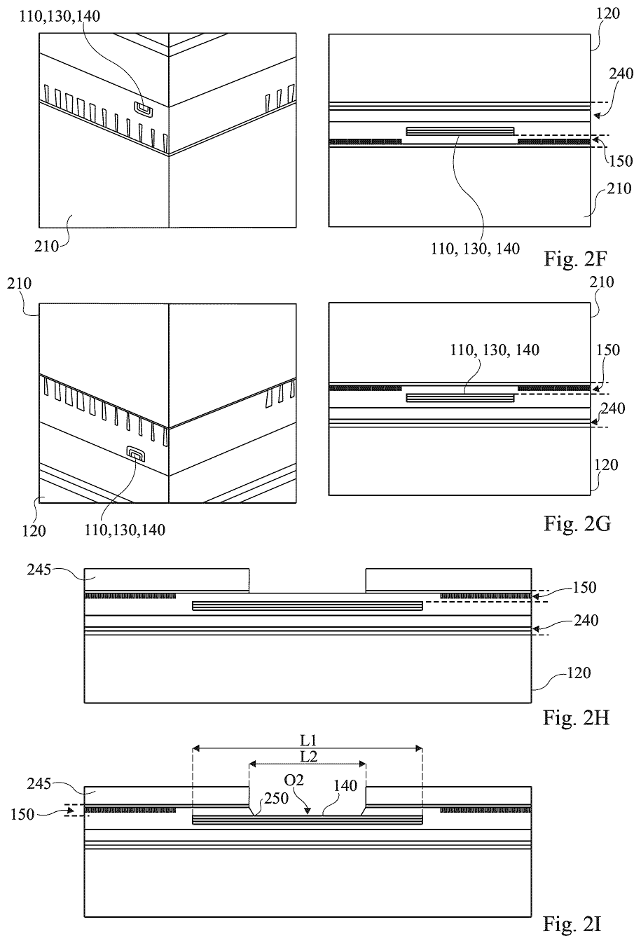

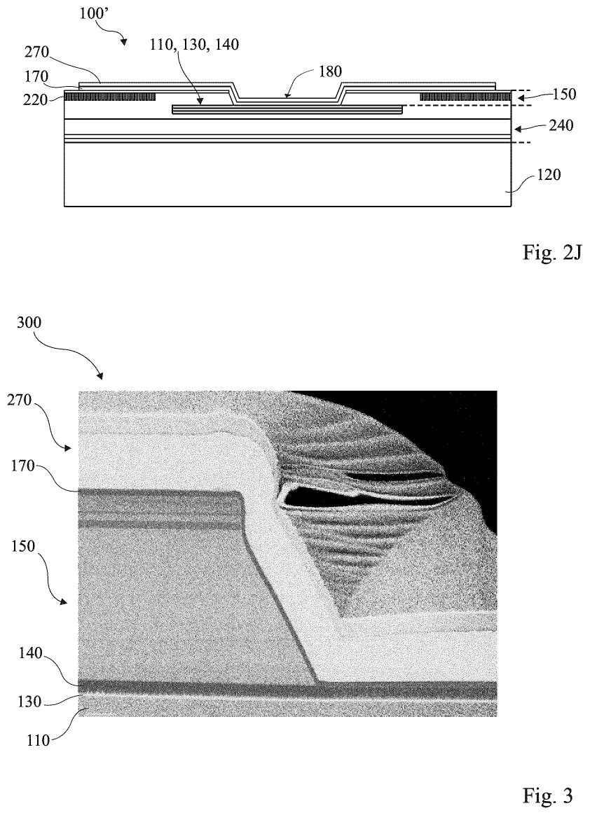

FIGS. 2A to 2G are perspective and cross-section views and FIGS. 2H to 2J are cross-section views of successive steps of a process for manufacturing the device 100 of FIGS. 1A and 1B according to an embodiment of the present disclosure.

Some elements of FIGS. 2A to 2J are identical to elements of FIGS. 1A and 1B, and these elements are designated by the same references and are not described again in detail.

FIG. 2A shows an example of a device 200 providing a starting point for the process for manufacturing the device 100 of FIGS. 1A and 1B.

The device 200 of FIG. 2A comprises the dielectric or semiconductor layer 150 of FIGS. 1A and 1B on a temporary substrate 210. In the example of FIG. 2A, layer 150 comprises a stack of dielectric and/or semiconductor layers and comprises an optical diffuser comprising, for example, polysilicon diffraction structures 220.

The stack of layers of layer 150 is for example obtained according to manufacturing steps known to those skilled in the art and which will not be detailed.

An optional first photolithography step is for example carried out to generate a first mask 230 on the first side F1 of layer 150 used for the forming of a first opening corresponding to trench O1. The first mask 230 is, for example, resist. Trench O1 represents, for example, a pattern corresponding to the trajectory of the metal track 110 of FIGS. 1A and 1B. The width L1 of trench O1 is, for example, greater than the width of metal track 110.

A first etch step is for example carried out after the photolithography step, to etch layer 150 at the position of trench O1.

After the first etch step, the first mask 230 is for example removed by abrasive polishing.

FIG. 2B shows the device 200 of FIG. 2A after a step of deposition of etch stop layer 140. Layer 140 at least partially covers the surface of layer 150 and, in particular, covers the walls of trench O1.

The deposition step is for example carried out by physical vapor deposition, chemical vapor deposition, etc.

Layer 140 is for example made of titanium nitride or of tantalum nitride. An advantage of using one of these materials is that they are already used for other applications in microelectronics, making the deposition processes easily feasible. The deposition processes involved in this disclosure, the interaction of these materials with the other materials of device 100, and the risks of pollution are known and controlled by those skilled in the art. Further, titanium nitride and tantalum nitride withstand a plasma etching process. In other embodiments, layer 140 is made of another material capable of forming an etch stop layer, in particular for plasma etching.

FIG. 2C shows the device of FIG. 2B after a step of deposition of diffusion barrier layer 130. Layer 130 at least partially covers the surface of layer 140 and, in particular, covers the walls of layer 140 in trench O1.

The deposition step is for example carried out by physical vapor deposition, chemical vapor deposition, etc.

FIG. 2D shows the device of FIG. 2C after a step of deposition of a metal layer 110′. According to an embodiment, prior to the step of deposition of metal layer 110′, particles of the first metallic material are for example deposited on the surface of layer 140, and are used as seeds for a process of electrolytic deposition of layer 110′. According to another embodiment, metal layer 110′ is for example deposited by chemical vapor deposition.

Metal layer 110′ at least partially covers the surface of layer 130 and, in particular, fills trench O1.

FIG. 2E shows the device of FIG. 2D after a thinning step. The device is for example thinned so as to expose the first side F1 of layer 150 outside trench O1. The thinning is for example performed by abrasive polishing.

After step 2E, the device comprises metal track 110. Metal track 110 corresponds to the thinned metal layer 110′ and is in contact on its lower side and its lateral sides with a stack of layers comprising layer 130 and layer 140.

FIG. 2F shows the device of FIG. 2E after one or a plurality of optional steps of deposition of layers 240. Layers 240 cover the surface of metal track 110 and are, for example, dielectric, conductive and/or semiconductor layers. Metal track 110 is, for example, in contact with a dielectric or semiconductor layer of the stack of layers 240.

According to an embodiment, the substrate 120 of the device 100 of FIG. 1A is bonded to the surface of layers 240.

According to another embodiment, in the absence of layers 240, substrate 120 is bonded to the surface of the first side F1 of layer 150 and covers the surface of layer 140.

FIG. 2G shows the device of FIG. 2F having been turned upside down to expose temporary substrate 210.

FIG. 2H shows the device of FIG. 2G after a thinning and photolithography step. The device is thinned, for example by chemical etching and/or abrasive polishing, to remove temporary substrate 210. Further, a second mask 245 is deposited on the surface of the second side F2 of layer 150. The second mask 245 is, for example, resist. The second mask comprises an opening aligned with the location of the opening O2 to be formed in layer 150.

FIG. 2I shows the device of FIG. 2H after an etch step, for example, plasma etching. The etching process is configured to form opening O2 and to at least partially expose layer 140.

Opening O2 extends from the second side F2 and runs through layer 150 to expose layer 140.

According to embodiments, layer 140 is partially etched. Layer 140 protects layer 130 during this etch step, in particular in corners 250.

Opening O2 has a width L2 which is, for example, smaller than or equal to the width L1 of trench O1.

The second mask 245 is for example removed at the end of the etch step, for example by a step of aqueous chemical cleaning. Layer 140 protects layers 130 and 110 from corrosion during this cleaning step.

FIG. 2J shows the device of FIG. 2I after a step of deposition of the first metallization layer 170. Layer 170 is deposited on the surface of the device of FIG. 2H and covers the surface of opening O2. Layer 170 is in contact with layer 150 and/or layer 140.

Metallization layer 170 is made of a second metallic material, for example gold, titanium, titanium tungsten, titanium nitride, etc., which is for example the same material or a material different from the first metallic material. Metallization layer 170 has a thickness in the range from 30 nm to 350 nm, for example from 250 nm to 350 nm.

According to an embodiment, step 2J is repeated a plurality of times and layer 170 is covered by one or a plurality of successively-deposited metal layers 270. For example, layer 170 is made of titanium, for example with a thickness in the range from 30 nm to 75 nm, after which a second layer made of titanium tungsten, for example with 10% of tungsten by weight, is deposited on the surface of layer 170, for example with a thickness in the range from 80 nm to 120 nm, and then a third layer made of gold, for example with a thickness in the range from 250 nm to 350 nm, is deposited on the surface of the second layer.

The corrosion potential of the second metallic material is higher than the corrosion potential of the first metallic material. The second metallic material is then less susceptible to corrosion than the first metallic material. For example, gold has a lower corrosion potential than copper. In particular, if metal track 110, or atoms of the first metallic material, come into contact with the second metallic material, then a galvanic corrosion may occur.

The assembly formed by layer 170 and metal layer(s) 270 if present, forms, for example, connection pad 180. In an optional etch step following step 2J, the final shape and dimensions of connection pad 180 are obtained.

At the end of step 2J is obtained a device 100′ similar to the device 100 of FIGS. 1A and 1B. In the example of FIG. 2J, layer 150 comprises a stack of layers and metal layer 270 is formed at the surface of layer 170.

According to an embodiment, the materials of layers 110, 130, 140, and 170 are distinct from one another.

Device 100′, comprising an optical diffuser, is a passive device configured to alter the propagation of a light beam (not illustrated). Device 100′ is for example configured to attenuate a light intensity of an incident laser beam, for example a laser having a power in the range from 1 W to 2 W. Metal track 110 is for example positioned on the optical path of the laser beam and configured to detect a failure of the optical diffuser of device 100′.

Layer 150 for example comprises polysilicon diffraction structures 220 and is for example configured to be partially transparent over a given wavelength range and to attenuate the light intensity of a laser beam crossing it. Metal track 110 is, for example, a safety track configured to break in case of tearing or of breakage of the optical diffuser. Metal track 110 is, for example, connected in a closed loop with the laser power supply. The laser is for example automatically switched off if metal track 110 is damaged.

FIG. 3 is a partial cross-section view of a device 300 comprising the metal track 110 of FIGS. 1A to 2J according to an embodiment of the present disclosure, acquired by transmission electron microscopy and energy-dispersive X-ray spectroscopy.

Some elements of FIG. 3 are identical to elements of FIGS. 1A and 1B, these elements are designated by the same references and are not described again in detail.

In the example of FIG. 3, three metal layers 270 cover the layer 170 of device 300.

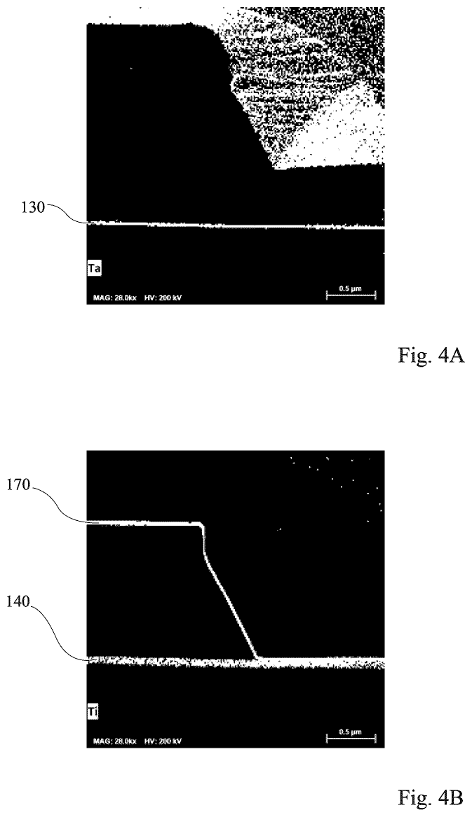

FIG. 4A shows the tantalum atoms comprised in the device of FIG. 3.

In the example of FIGS. 3 and 4A, layer 130 comprises tantalum, for example tantalum or tantalum nitride. FIG. 4A illustrates that layer 130 is intact after the etching process of step 2I. Metal track 110 remains entirely covered by layer 130.

FIG. 4B shows the titanium atoms comprised in the device of FIG. 3.

In the example of FIGS. 3 and 4B, layer 140 comprises titanium, it is for example made of titanium or of titanium nitride. Layer 140 covers layer 130 to protect it during the etching process of step 2I. Layer 170 is for example made of titanium. FIG. 4B illustrates that layer 140 is intact after the etching process of step 2I. Layer 130 is effectively protected by layer 140 during the etching process of step 2I.

Device 100 is, for example, a connection interface between a component or an electronic chip and its outer environment.

Device 100 is, for example, a one-time programmable memory cell.

Device 100 is for example an electronic and/or optical system comprising a metal line, for example configured for a routing of information, an electric power supply, or a tamper indicator for the device.

The device 100 of FIGS. 1A and 1B, the device 100′ of FIG. 2J, and the device 300 of FIGS. 3, 4A, and 4B, for example have many applications in many industrial sectors. For example, device 100, 100′, 300 is integrated in a system comprising one or a plurality of other components.

The system is for example intended to be implemented in electronic systems for personal use, for example in connected systems, for example by using a 5G or radio frequency connection. The system is for example a cell phone or forms part of a network of a connected object. The system communicates, for example, with 5G, WIFI, or in ultra-broadband. The system for example comprises high-speed interfaces, for example with an advanced filtering and an electromagnetic discharge protection. For example, the system is used in face recognition systems in personal electronics, for example in cell phones or laptops, or in telemetry systems, for example comprised in tablet computers, or depth sensors.

The system is for example intended to be implemented in communications equipment or in computers and peripherals. For example, the system is used in 5G infrastructures and dedicated data centers. The system for example comprises silicon carbide diodes, Schottky transistors, electromagnetic discharge protection, and transient voltage suppression diodes. The system is for example used in a satellite, for example comprising integrated passive systems for radio frequency applications.

The system for example implements three-dimensional (3D) technologies during its manufacturing, that is, implementations by a stack of a plurality of silicon tiers. The system is, for example, a reprogrammable non-volatile memory cell or a stacked image sensor connected on its back side, for example, a backside-illuminated sensor formed by 3D technologies.

An advantage of the presence of etch stop layer 140 at the surface of diffusion barrier layer 130 is a better protection of metal track 110 to decrease risks of electromigration and corrosion.

Avoiding or decreasing the etching of diffusion barrier layer 130 during the step of FIG. 2I is also advantageous in the case where this barrier layer 130 is made of a type of material, for example tantalum, which generates difficult-to-remove polymer residues. However, it is possible to form etch stop layer 140 in a material generating less polluting residues.

Another advantage of the various disclosed embodiments is that the strength of the stack of layers formed of layers 110, 130, 140, and 170 is little altered by the presence of layer 140.

Various embodiments and variants have been described. Those skilled in the art will understand that certain features of these various embodiments and variants could be combined, and other variants will become apparent to those skilled in the art. In particular, although embodiments have been described in which a metal track is electrically connected to a connection pad, in other embodiments, the metal track could be connected to other structures.

Finally, the practical implementation of the described embodiments and variants is within the abilities of those skilled in the art, based on the functional indications given hereabove.

Device (100, 100′) is summarized as including: on a substrate: a dielectric or semiconductor layer (150); a trench (O1) in the dielectric or semiconductor layer (150) extending from a first side (F1) of the dielectric or semiconductor layer (150), the trench partially running through the dielectric or semiconductor layer (150) and being filled with: a conductive etch stop layer (140) covering the walls of the trench (O1) and in contact with the dielectric or semiconductor layer (150); a conductive barrier layer (130) covering the conductive etch stop layer (140); and a track (110) of a first metallic material in contact with the barrier layer (130), in the trench (O1); an opening (O2) in the dielectric or semiconductor layer (150) extending from a second side (F2), opposite to the first side (F1), of the dielectric or semiconductor layer (150), the opening running through the dielectric or semiconductor layer (150) all the way to the etch stop layer (140); and a first layer (170) of a second metallic material covering the walls of the opening (O2).

The first layer (170) of the second metallic material forms a connection pad (180).

Device (100, 100′) is summarized as including a second layer (270) of a third metallic material covering the first layer, the third metallic material being, for example, gold, titanium, or titanium tungsten.

The track (110) is a safety track configured to break in case of a tearing or of a breakage of the optical diffuser.

Manufacturing process is summarized as including: on a substrate: an etching of a trench (01) in a dielectric or semiconductor layer (150) extending from a first side (F1) of the dielectric or semiconductor layer (150), the trench partially running through the dielectric or semiconductor layer (150); a deposition of a conductive etch stop layer (140) covering the walls of the trench (O1) and in contact with the dielectric or semiconductor layer (150); a deposition of a conductive barrier layer (130) covering the conductive etch stop layer (140); a deposition of a track (110) made of a first metallic material in contact with the barrier layer (130), into the trench (O1); an etching of an opening (O2) in the dielectric or semiconductor layer (150) extending from a second side (F2), opposite to the first side (F1), of the dielectric or semiconductor layer (150), the opening running through the dielectric or semiconductor layer (150) until exposing a portion of the conductive etch stop layer (140); and a deposition of a first layer (170) of a second metallic material covering the walls of the opening (O2).

Process further includes, prior to the step of deposition of the track (110), a step of deposition of particles of the first metallic material on the surface of the barrier layer (130), the particles being used as seeds for the deposition of the track (110).

The deposition of the track (110) is performed by electroplating.

Process further includes, prior to the etching of the opening (O2), a thinning step to expose the dielectric or semiconductor layer (150) outside the trench (O1).

The opening (O2) is formed by plasma etching.

The process further includes, prior to the etching the opening (O2), the thinning of the substrate to expose the second side (F2) of the dielectric or semiconductor layer (150).

The conductive etch stop layer (140) is made of titanium nitride and for example has a maximum thickness in the range from 30 nm to 100 nm.

The barrier layer (130) is made of tantalum nitride or of tantalum.

The first metallic material is copper.

The second metallic material is gold, titanium, or titanium tungsten.

The use of the device (100, 100′) is summarized as including the application of a current to the track (110) and the detection of an open circuit preventing the conduction of this current.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a substrate;
a dielectric or semiconductor layer on the substrate, the dielectric or semiconductor layer having a trench extending from a first surface of the dielectric or semiconductor layer, the trench partially extending through the dielectric or semiconductor layer; a conductive etch stop layer covering walls of the trench and in contact with the dielectric or semiconductor layer and the substrate;
a conductive barrier layer covering the conductive etch stop layer and in contact with the substrate; and a track of a first metallic material in the trench and in contact with the barrier layer and the substrate; an opening in the dielectric or semiconductor layer extending from a second surface, opposite to the first surface, of the dielectric or semiconductor layer, the opening extending through the dielectric or semiconductor layer to the etch stop layer; and a first layer of a second metallic material covering walls of the opening.

2. The device according to claim 1, wherein the first layer of the second metallic material is a connection pad.

3. The device according to claim 1, comprising a second layer of a third metallic material covering the first layer, the third metallic material is gold, titanium, or titanium tungsten.

4. An optical diffuser comprising the device according to claim 1, wherein the track is a safety track configured to break in case of a tearing or of a breakage of the optical diffuser.

5. A manufacturing process, comprising:
etching a trench in a dielectric or semiconductor layer on a substrate, the trench extending from a first surface of the dielectric or semiconductor layer, the trench partially extending through the dielectric or semiconductor layer; depositing a conductive etch stop layer covering walls of the trench and in contact with the dielectric or semiconductor layer;
depositing a conductive barrier layer covering the conductive etch stop layer;
depositing a track made of a first metallic material in contact with the barrier layer, into the trench;
etching an opening in the dielectric or semiconductor layer extending from a second surface, opposite to the first surface, of the dielectric or semiconductor layer, the opening extending through the dielectric or semiconductor layer until exposing a portion of the conductive etch stop layer; and
depositing a first layer of a second metallic material covering walls of the opening.

6. The process according to claim 5, further comprising, prior to depositing the track, depositing particles of the first metallic material on the barrier layer, the particles being used as seeds for the depositing of the track.

7. The process according to claim 5, wherein depositing the track is carried out by electroplating.

8. The process according to claim 5, further comprising, prior to etching the opening, thinning to expose the dielectric or semiconductor layer outside the trench.

9. The process according to claim 5, wherein the opening is formed by plasma etching.

10. The process according to claim 5, further comprising, prior to etching the opening, thinning of the substrate to expose the second surface of the dielectric or semiconductor layer.

11. The device according to claim 1, wherein the conductive etch stop layer is made of titanium nitride and has a maximum thickness ranging from 30 nm to 100 nm.

12. The device according to claim 1, wherein the barrier layer is made of tantalum nitride or tantalum.

13. The device according to claim 1, wherein the first metallic material is copper.

14. The device according to claim 1, wherein the second metallic material is gold, titanium, or titanium tungsten.

15. Use of the device according to claim 1, comprising application of a current to the track and detection of an open circuit preventing the conduction of the current.

16. A device comprising:
a substrate having a first surface;
a conductive track on the first surface of the substrate;
a first conductive layer on the conductive track and coupled with the first surface of the substrate;
a second conductive layer on the first conductive layer and coupled with the first surface of the substrate;
an insulating layer on portions of the second conductive layer and coupled with the first surface of the substrate, the insulating layer having:
a first surface in contact with the first surface of the substrate;
a second surface opposite the first surface; and
a trench in the second surface; and
a third conductive layer on the insulating layer, the third conductive layer in the trench and on the second conductive layer.

17. The device of claim 16, wherein the first conductive layer is made of tantalum nitride, tantalum, or aluminum.

18. The device of claim 16, wherein the second conductive layer is a continuous layer entirely covering the first conductive layer.

19. The device of claim 16, wherein the third conductive layer is made of gold, titanium, titanium tungsten, or titanium nitride.

20. The device of claim 16, wherein the first conductive layer extends on a first surface and lateral surfaces of the conductive track, the first surface of the conductive track opposite the first surface of the substrate, the lateral surfaces of the conductive track being transverse the first surface of the conductive track.
